(19) United States
(12) Patent Application Publication
(10) Pub. No.: US 2007/0081613 A1
(43) Pub. Date: Apr. 12, 2007

(54) Ultra wideband networks system and method capable of switching to high-speed mode or low-speed mode

(75) Inventors: Wan-jin Kim, Seoul (KR); Jae-hyun Koo, Seoul (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 11/490,029

(22) Filed: Jul. 21, 2006

(30) Foreign Application Priority Data
Sep. 28, 2005 (KR) 10-2005-0090698

(51) Int. Cl. H03D 3/24

(52) U.S. Cl. 375/327

(57) ABSTRACT

An ultra wideband network transmitter and receiver, and a method capable of switching to a high-speed mode or a low-speed mode are provided. The transmitter includes a multi-band orthogonal frequency division multiplexing (MB-OFDM) modem; a direct sequence code division multiple access (DS-CDMA) modem; a mode switch which switches to the MB-OFDM modem or the DS-CDMA modem according to a mode control signal; a phase lock loop (PLL) which locks a frequency used for MB-OFDM type modulation or the DS-CDMA type modulation; and a central processing unit (CPU) controls the PLL and mode switch. The receiver includes an MB-OFDM modem; an DS-CDMA modem; an automatic gain controller; an analog-to-digital converter; an PLL; a mode switch; and an CPU. The method includes receiving a command to transmit data; and switching to an MB-OFDM modem to select to a high-speed operation mode.

### CROSS-REFERENCE TO RELATED APPLICATION

This application claims priority from Korean Patent Application No. 10-2005-0090698, filed Sep. 28, 2005 in the Korean Intellectual Property Office, the entire contents of which are incorporated herein by reference.

### BACKGROUND OF THE INVENTION

1. Field of the Invention

Apparatuses, systems, and methods consistent with the present invention relate to an ultra wideband network communications, and more particularly, to switching to a high-speed mode or a low-speed mode, in order for an ultra wideband communication terminal device such as a home network device to selectively perform high-speed communications or low-speed communications.

2. Description of the Related Art

In general, ultra wideband (UWB) is a wireless transmission technology whose a frequency bandwidth is 20 percent or 500 MHz more than a central frequency bandwidth. Accordingly, bandwidth gets broader in the frequency band and conversely, the transmission power density gets lower on the frequency axis.

Federal Communications Commission (FCC) sets approximately 3.1 GHz to approximately 10.6 GHz for a frequency band for UWB communication and sets −41.3 dBm as a limit of power emission.

There are two UWB communication methods currently available which satisfy the limits placed on power emission. One is a multi-band orthogonal frequency division multiplexing (MB-OFDM) method in which the band of approximately 3.1˜10.6 GHz is divided by 528 MHz and each resulting band is frequency-hopped using an UWB signal of an OFDM type. The other one is a direct sequence code division multiple access (DS-CDMA) method in which the band of approximately 3.1˜10.6 GHz is divided in half and a 24-bit codeword is substituted for a bit sequence of each band using an UWB signal.

FIG. 1A is a schematic block diagram showing the structure of a wireless frequency transceiver of a conventional MB-OFDM type.

The wireless frequency transceiver of the conventional MB-OFDM type includes a low-pass filter (LPF) 102, a transmission mixer 104, a Wilkinson combiner 106, a drive amplifier (drive amps) 108, a switch 110, a low noise amplifier (LNA) 112, a Wilkinson demultiplier 114, a reception mixer 116, an amplifier 118, an LPF 120, a variable gain amplifier (VGA) 122, a multi-tone generator 130, a voltage control oscillator (VCO) 132 and a phase lock loop (PLL) 134.

When the above described wireless frequency transceiver of the conventional MB-OFDM type transmits data, an oscillation frequency of the VCO 132 generates a local oscillation signal of an I channel and a local oscillation signal of a Q channel through the multi-tone generator 130, the transmission mixer 104 mixes the local oscillation signals of the I channel and the Q channel and the transmission signal filtered through the LPF 102, the Wilkinson combiner 106 combines the mixed signal of the I channel and the mixed signal of the Q channel, the combined signal is amplified through the drive amps 108 and is transmitted through an antenna (Ant). This process is performed by switching to a transmission mode using the switch 110.

On the other hand, when the wireless frequency transceiver of the conventional MB-OFDM type receives data, the switch 110 switches to a reception mode to process the received data. The LNA 112 amplifies a signal received through the antenna, the Wilkinson demultiplier 114 divides the amplified signal into an I channel signal and a Q channel signal, and the reception mixer 116 mixes the received signal with a local oscillation signal of an I channel and a local oscillation signal of a Q channel. Subsequently, the mixed signal is amplified by the amplifier 118, filtered by the LPF 120 and amplified by the VGA 122 to input I channel data and Q channel data respectively.

FIG. 1B is a schematic block diagram showing the structure of a wireless frequency transceiver of a conventional DS-CDMA type.

The wireless frequency transceiver of the conventional DS-CDMA type includes an oscillator 140, a band selector (/N) 142, a demultiplier (/L) 144, a data transfer part 146, a code generator 150, a mixer 152, a low pass filter (LPF) 154, a mixer 156, a multiplier 158, a drive amplifier 160, an amplifier 162, a sense 164, a filter 166, a LNA 168 and a receiver 170.

The above described wireless frequency transceiver of the conventional DS-CDMA type oscillates agile clock of 1.352 GHz through the oscillator 140. Subsequently, in the case of n=1, the band selector 142 selects frequency of 1.5 GHz bandwidth used in IEEE 802.15.TG3a, or in the case of n=3, the band selector 142 selects frequency of 500 MHz bandwidth used in IEEE 802.15.TG4a. Commonly, n is set to I upon a high-speed mode and to 3 upon a low-speed mode. The frequency of the band selected through the band selector 142 is transmitted through the multiplier 158 to the mixer 156 of a transmitter as a chip rate clock or transmitted through the demultiplier 144 to the receiver 170 as a symbol rate clock. Additionally, the chip rate clock and symbol rate clock are also transmitted to the code generator 150. In the case of data transmission, the code generator 150 generates a ternary code of ‘+1, 0, −1’ based on the chip rate clock and symbol rate clock, and transmits the ternary code to the mixer 152, and the data transfer part 146 transmits data received from a CPU or a memory to the mixer 152 based on the symbol rate clock. The mixer 152 mixes the ternary code and the data and transmits the result to the LPF 154 and the LPF 154 filters the combined data and transmits the data to the mixer 156. The mixer 156 receives the chip rate clock from the band selector 142 in both a high-speed mode of n=1 and a low-speed mode of n=3, receives the combined data and mixes both together. Next, the mixed data are amplified through the drive amplifier 160 and the amplifier 162, are filtered through the filter 166 and are transmitted through an ANT. Herein, the mixed data are amplified through the amplifier 162, regulated through the sense 164 and transmitted to the filter 166.

When the wireless frequency transceiver of the conventional DS-CDMA type receives data, the received signal is amplified through the LNA 168 and transmitted to the receiver 170. The receiver 170 mixes, amplifies, integrates, samples and holds the received signal and the clock signal to transmit to an analog to digital (A/D) converter.

However, even though many companies adopt the MB OFDM type method for high-speed communication, this method is not appropriate for a low-power sensor network system mainly using a location recognition technology. In addition, because the MB-OFDM technology is not compatible with other sensor network systems, an extra transceiver is needed to subscribe to the sensor network systems.

On the other hand, in the case of the DS-CDMA type method, it is easy to share the transceiver in the high-speed mode and the low-speed mode as above described. However, the high-speed mode of the DS-CDMA is not adopted by many companies so that compatibility is low.

Additionally, when a transceiver of the MB-OFDM type and a transceiver of the DS-CDMA type are used at the same time, because the communication types are different, each transceiver interprets the other transceiver's frequencies as noise so that serious interference occurs.

### SUMMARY OF THE INVENTION

An aspect of the present invention is to address the above and other problems and/or disadvantages. Accordingly, an aspect of the present invention is to provide an ultra wideband network system and a method capable of switching to a high-speed mode or a low-speed mode, in order for an ultra wideband communication terminal device such as home network devices to perform high-speed communications and low-speed communications.

In order to achieve the above-described aspect of the present invention, there is provided an ultra wideband (UWB) network transmitter, comprising a multi-band orthogonal frequency division multiplexing (MB-OFDM) modem which modulates a transmission signal using MB-OFDM; a direct sequence code division multiple access (DS-CDMA) modem which modulates a transmission signal using DS-CDMA; a mode switch which switches to the MB-OFDM modem or the DS-CDMA modem according to a mode control signal; a phase lock loop (PLL) which shifts a phase of a frequency according to a phase control signal and locks the frequency used for MB-OFDM type or the DS-CDMA type modulation; and a central processing unit (CPU) which transmits the mode control signal to the mode switch and transmits the phase control signal to the PLL.

The mode control signal may be a high-speed mode control signal or a low-speed mode control signal.

The CPU may transmit the mode control signal to the mode switch and the phase control signal to the PLL, according to a mode selection input.

The UWB network transmitter may further comprise a low-pass filter (LPF) which filters out a high frequency noise component of a signal output from the MS-OFDM modem or the DS-CDMA modem and passes a low frequency component of the signal; a mixer which mixes the signal output from the LPF and an oscillation signal to up-convert the signal; an amplifier which amplifies the up-converted signal; a band-pass filter (BPF) which passes a frequency band of an MB-OFDM type or a frequency band of an DS-CDMA type; a voltage control oscillator (VCO) which generates a voltage-controlled oscillation signal according to a control voltage; and a multi-tone generator which receives the voltage-controlled oscillator signal and generates the oscillation signal as a local oscillation signal of an I channel and a Q channel.

When there is no data to be transmitted, the mode switch may be switched to the DS-CDMA modem so that the UWB network transmitter is in a low-speed operation mode.

The CPU may determine whether to keep the high-speed operation mode after transmitting data, and when it is determined that a low-speed operation mode is desired, the CPU may transmit a low-speed mode control signal to the mode switch.

The PLL may comprise a reference clock generator which generates a reference frequency; a divider which divides the reference frequency to generate a division frequency; a mixer which mixes the division frequency and a demultiply frequency to detect phase; a LPF which blocks a high frequency noise component of a signal output from the mixer and passes a low frequency component of the signal; and a low noise amplifier (LNA) which amplifies the signal output from the LPF and lowers a noise factor of the frequency signal and transmits the signal to the VCO; and a demultiplier which demultiplies the signal output from the VCO and generates a chip rate clock signal and a symbol rate clock signal.

There is also provided an ultra wideband (UWB) network receiver comprises a multi-band orthogonal frequency division multiplexing (MB-OFDM) modem which demodulates digital reception data of an MB-OFDM type; a direct sequence code division multiple access (DS-CDMA) modem which demodulates digital reception data of an DS-CDMA type; an automatic gain controller (AGC) which controls the amplitude of an input signal and outputs the signal as an analog reception signal; an analog-to-digital converter which converts the analog reception signal into the digital reception data; a phase locked loop (PLL) which locks a phase of a frequency used for MB-OFDM type or DS-CDMA; a mode switch which switches the digital reception data to the MB-OFDM modem or the DS-CDMA modem according to a mode control signal; and a central processing unit (CPU) which determines if data are processed according to the MB-OFDM type or the DS-CDMA type, transmits the mode control signal to the mode switch, and transmits a phase control signal to the PLL.

The mode control signal may be a high-speed mode control signal or a low-speed mode control signal.

The UWB receiver may further comprise an analog matched filter which integrates, samples, and holds an amplified signal; and an amplifier which amplifies the input signal and outputs an amplified signal to the analog matched filter and the AGC; wherein the PLL transmits a symbol rate clock to the analog matched filter to control the phase of the filtered signal.

The UWB network receiver may further comprise a band pass filter (BPF) which filters a reception signal, and passes a signal of a frequency band of the MB-OFDM type or a frequency band of the DS-CDMA type; a low noise amplifier (LNA) which amplifies the signal from the BPF and lowers a noise factor of the UWB network receiver; a voltage controlled oscillator (VCO) which generates an oscillation signal according to a control voltage from the PLL; a mixer which mixes the amplified signal and the oscillation signal; a low pass filter (LPF) which blocks a high frequency noise component of the mixed signal and passes a signal of a low frequency band to the AGC; and a multi-tone generator which generates the oscillation signal as a local oscillation signal of an I channel and a Q channel and transmits the oscillation signal to the mixer.

When there is no data received, the mode switch may be switched to the DS-CDMA modem so that the UWB network transmitter is in the low-speed operation mode.

There is also provided a method of switching transmission modes in an ultra wide band network transmitter, the method comprising: receiving a command to transmit data; and switching to a multi-band orthogonal frequency division multiplexing (MB-OFDM) modem to select a to the high-speed operation mode.

The method may further comprise transmitting the data in the high-speed operation mode.

After the data is transmitted, whether to remain in the high-speed operation mode may be determined, and when a low-speed operation mode is desired, switching to the direct sequence code division multiple access (DS-CDMA) modem to select the low-speed operation mode.

### BRIEF DESCRIPTION OF THE DRAWING FIGURES

The above and other aspects of the present invention will become more apparent by describing in detail exemplary embodiments thereof with reference to the attached drawing figures, wherein;

FIG. 1A is a schematic diagram showing the construction of a wireless frequency transceiver of a conventional MB-OFDM type;

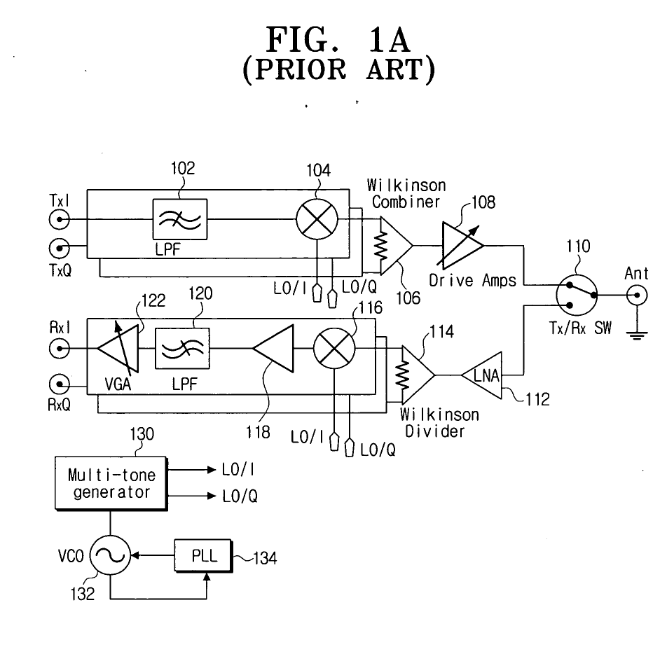

FIG. 1B is a schematic diagram showing the construction of a wireless frequency transceiver of a conventional DS-CDMA type;

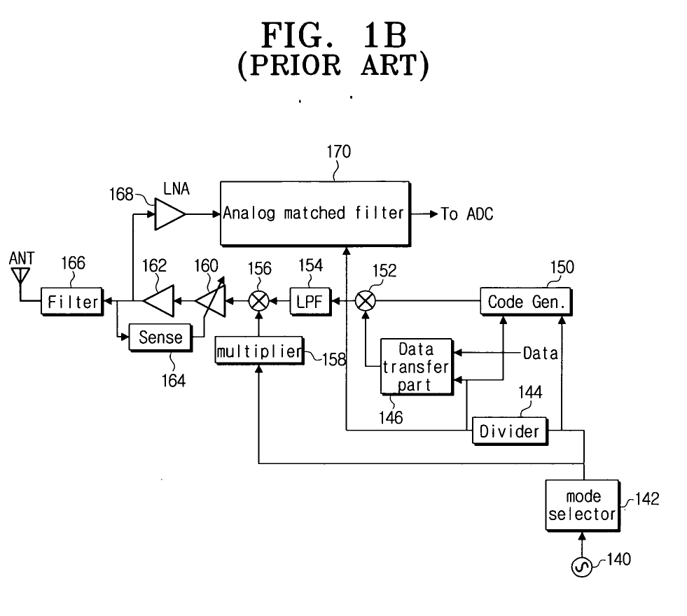

FIG. 2 is a schematic diagram showing the construction of a UWB network transmitter according to an exemplary embodiment of the present invention;

FIG. 3 is a schematic diagram showing the construction of a UWB network receiver according to an exemplary embodiment of the present invention;

FIG. 4 is a schematic diagram showing the construction of a UWB network receiver without an analog matched filter according to an exemplary embodiment of the present invention;

FIG. 5 is a schematic diagram showing the construction of a PLL according to an exemplary embodiment of the present invention; and

FIG. 6 is a flow chart showing the operation of a UWB network switching method according to an exemplary embodiment of the present invention.

### DETAILED DESCRIPTION OF EXEMPLARY EMBODIMENTS OF THE PRESENT INVENTION

Hereinafter, an exemplary embodiment of the present invention will be described in detail with reference to the accompanying drawing figures.

In the following description, same drawing reference numerals are used for the same elements even in different drawings. The matters defined in the description such as a detailed construction and elements are nothing but the ones provided to assist in a comprehensive understanding of the invention. Thus, it is apparent that the present invention can be carried out without those defined matters. Also, well-known functions or constructions are not described in detail since they would obscure the invention in unnecessary detail.

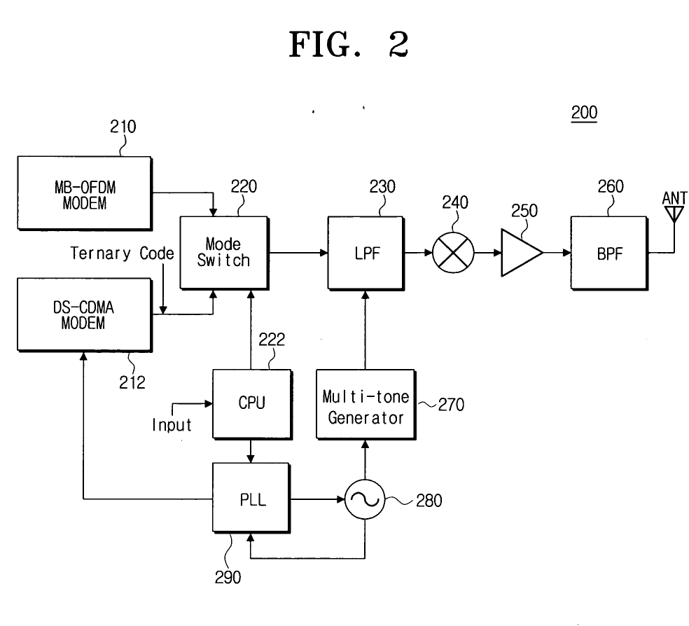

FIG. 2 is a schematic diagram showing the construction of a UWB network transmitter according to an exemplary embodiment of the present invention.

The UWB network transmitter 200 according to an exemplary embodiment of the present invention includes an MB-OFDM modem 210, a DS-CDMA modem 212, a mode switch 220, a central processing unit (CPU) 222, a low-pass filter (LPF) 230, a mixer 240, an amplifier 250, a band-pass filter (BPF) 260, a multi-tone generator 270, a voltage controlled oscillator (VCO) 280 and a phase lock loop (PLL) 290.

The MB-OFDM modem 210 modulates a transmission signal of the MB-OFDM type and the DS-CDMA modem 212 modulates a transmission signal of the DS-CDMA type.

The mode switch 220 switches to the MB-OFDM modem 210 or the DS-CDMA modem 212 according to a mode control signal, which may be a high-speed mode control signal or a low-speed mode control signal, transmitted from the CPU 222.

The CPU 222 transmits the mode control signal, i.e. high-speed mode control signal or the low-speed mode control signal, to the mode switch 220 according to a mode selection input. The mode selection input may come from a user. Additionally, the CPU 222 transmits a phase control signal to the PLL 290 to control a phase of a frequency to be used in the corresponding operation mode according to the mode selection input.

The LPF 230 filters a high frequency noise component of a signal and passes a signal of a low frequency band.

The mixer 240 mixes the transmission signal and an oscillation signal, thus up-converting the transmission signal. The amplifier 250 amplifies the up-converted transmission signal. The up-converted transmission signal is a radio frequency (RF) signal.

The BPF 260 passes a frequency band corresponding to the MB-OFDM modulation type or a frequency band corresponding to the DS-CDMA modulation type and filters out other frequency components.

The multi-tone generator 270 generates the oscillation signal as a local oscillation signal of an I channel and a Q channel and the VCO 280 generates a voltage-controlled oscillation signal according to a control voltage.

The PLL 290 shifts a frequency phase according to a phase control signal transmitted from the CPU 222 and locks the frequency phase according to which modulation is selected, i.e. the MB-OFDM type or the DS-CDMA type modulation.

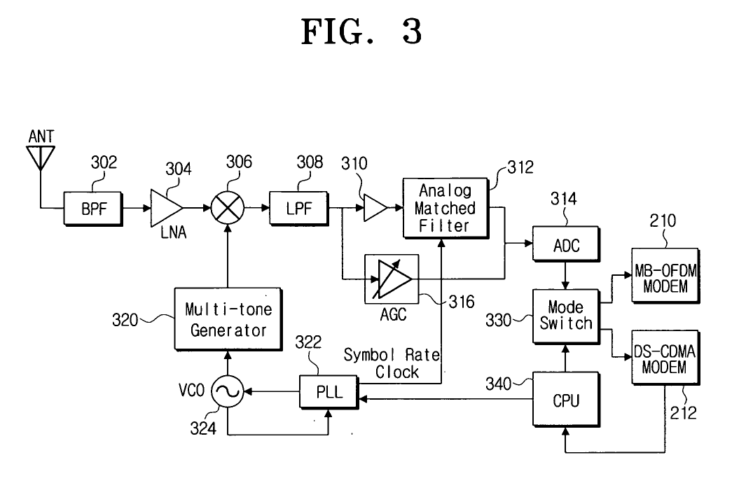

FIG. 3 is a schematic diagram showing the construction of a UWB network receiver according to an exemplary embodiment of the present invention.

The UWB network receiver 300 according to the present invention includes a band-pass filter (BPF) 302, a low noise amplifier (LNA) 304, a mixer 306, a low-pass filter (LPF) 308, an amplifier 310, an analog matched filter 312, an analog-to-digital converter (ADC) 314, an automatic gain controller (AGC) 316, a multi-tone generator 320, a phase lock loop (PLL) 322, a voltage controlled oscillator (VCO) 324, a mode switch 330, a central processing unit (CPU) 340, an MB-OFDM modem 210, an DS-CDMA modem 212.

The BPF 302 passes a signal of a frequency band corresponding to the MB-OFDM type modulation or a frequency band corresponding to the DS-CDMA type modulation and filters out other frequency components of the signal. The LNA 304 is a high frequency, low noise amplifier to lower a noise factor of the overall receiver.

The mixer 306 mixes a reception signal output from the LNA and an oscillation signal. The LPF 308 filters a high frequency noise component of the signal output from the mixer and passes a signal of a low frequency band.

The amplifier 310 amplifies the filtered reception signal. The analog matched filter 312 integrates, samples and holds the reception signal.

The AGC 316 automatically controls the amplitude of the reception signal to keep the amplitude regular. The ADC 314 converts the gain-controlled analog reception signal into digital reception data.

The VCO 324 generates a voltage-controlled oscillation signal according to a control voltage. The multi-tone generator 320 receives the voltage-controlled oscillation signal and generates the oscillation signal as a local oscillation signal of I channel and Q channel, and transmits the signal to the mixer 306.

The PLL 322 locks the frequency phase according to whether the MB-OFDM type or the DS-CDMA type modulation is used and transmits a symbol rate clock to the analog matched filter 312 to control the phase of the reception signal.

The mode switch 330 switches to the MB-OFDM modem 210 or the DS-CDMA modem 212 according to a mode control signal, which may be a high-speed mode control signal or a low-speed mode control signal, transmitted from the CPU 340. It is common for the mode switch 330 to switch to the DS-CDMA modem 212.

The CPU 340 determines if reception data is processed using the MB-OFDM type or the DS-CDMA type modulation and transmits a mode control signal, i.e. a high-speed mode control signal or a low-speed mode control signal, to the mode switch 330. Additionally, the CPU 222 transmits a phase control signal to the PLL 322 to control a phase of a frequency to be used in the corresponding operation mode according to the mode control signal.

The MB-OFDM modem 210 modulates the reception signal using the MB-OFDM type modulation and the DS-CDMA modem 212 modulates the reception signal using the DS-CDMA type modulation.

The receiver of FIG. 3 uses the conventional analog reception construction which uses both the AGC 316 and the analog matched filter 312 so that the ADC 314 operates at a low-speed. As a result, the power consumption of the ADC 314 decreases.

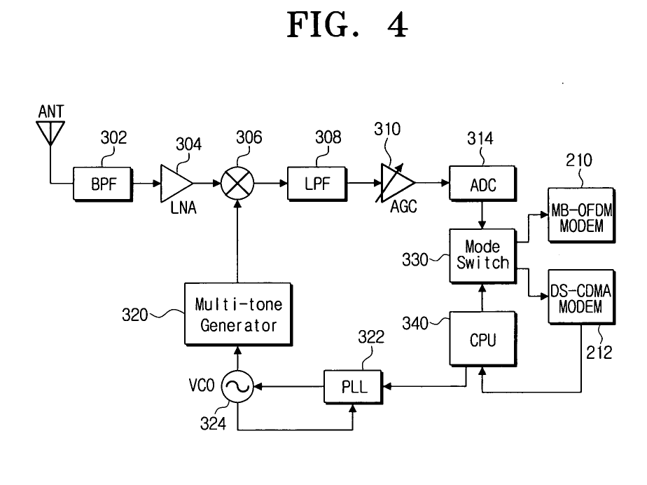

FIG. 4 is a schematic diagram showing the construction of a UWB network receiver without an analog matched filter according to an exemplary embodiment of the present invention.

The receiver of FIG. 4 excludes the analog matched filter 312 and uses the AGC 316 instead of the amplifier 310.

Accordingly, the reception signal passes through the LPF 308, is amplified in the AGC 316 and is transmitted directly to the ADC 314.

Therefore, the ADC 314 operates at a high-speed to immediately covert the analog reception signal into digital reception data. That is, a high-speed A/D converter is used and functions as a digital matched filter.

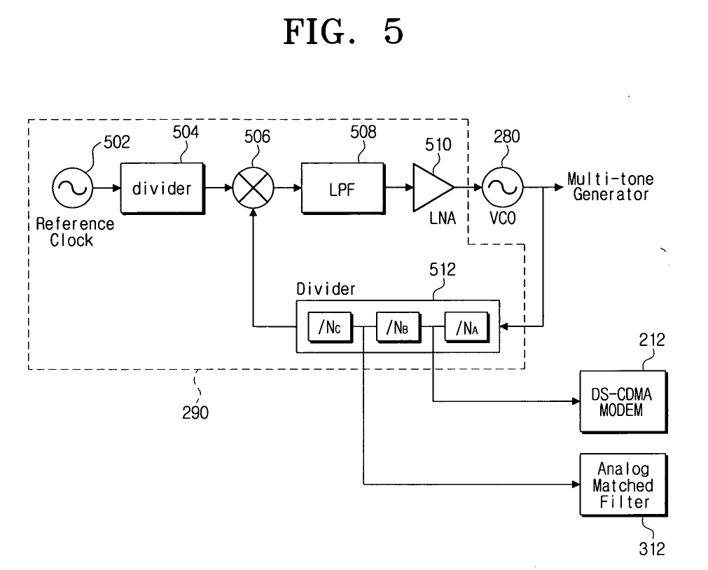

FIG. 5 is a schematic diagram showing the construction of a PLL according to an exemplary embodiment of the present invention.

The PLL 290 according to an exemplary embodiment of the present invention includes a reference clock generator 502, a divider 504, a mixer 506, a low pass filter (LPF) 508, a low noise amplifier (LNA) 510 and a demultiplier 512.

The reference clock generator 502 generates a reference frequency and the divider 504 divides the reference frequency to generate a division frequency f1. The mixer 506 mixes the division frequency f1 and a demultiply frequency to detect phase.

Additionally, the LPF 508 filters out a high frequency noise component of the mixed frequency signal and passes a frequency signal of the low frequency band, and the LNA 510 lowers a noise factor of the frequency signal and transmits the frequency signal to a VCO 280.

The demultiplier 512 demultiplies the frequency signal fed back from the VCO 280 and generates a chip rate clock signal and a symbol rate clock signal. That is, the demultiplier 512 generates a chip rate clock signal of about 500 MHz on the first demultiplying (/N_{A}) to transmit to the DS-CDMA modem 212, generates a symbol rate clock signal on the order of about several hundreds of kilohertz to several MHz on the second demultiplying (/N_{B}) to transmit to the analog matched filter 312 and transmits the demultiplied frequency to the mixer 506 on the third demultiplying (/N_{C}).

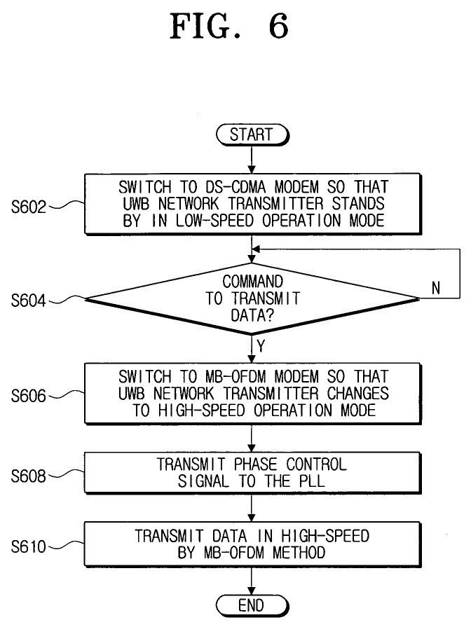

Referring to FIG. 6, the operation of a UWB network switching method according to an exemplary embodiment of the present invention will be described.

First, usually when data is not transmitted, the mode switch 220 selects the DS-CDMA modem 212 so that the UWB network transmitter 200 stands by in the low-speed operation mode (S602). The selection may occur by the mode switch connecting to the DS-CDMA modem 212.

Subsequently, if a command is received to transmit mass data (S604), the CPU 222 transmits a high-speed mode control signal to the mode switch 220. Accordingly, the mode switch 220 switches to the MB-OFDM modem 210 so that the UWB network transmitter 200 changes to the high-speed operation mode (S606). The command may be input by a user's key input.

In addition, the CPU 222 transmits a phase control signal to the PLL 290 to select the frequency phase of the MB-OFDM type (S608). Accordingly, the PLL 290 shifts the frequency phase to the frequency phase of the MB-OFDM type according to the phase control signal to control the frequency phase.

Further, the mass data passes through MB-OFDM modem 210, the LPF 230, the mixer 240, the amplifier 250 and the BPF 260, as described above, and is transmitted through the ANT under the control of the CPU 222 (S610).

The CPU 222 determines whether to keep the high-speed operation mode after transmitting the mass data. When it is determined to use the low-speed operation mode, the CPU 222 transmits a low-speed mode control signal to the mode switch 220. Accordingly, the mode switch 220 selects the DS-CDMA modem 212 so that the UWB network transmitter 200 changes to the low-speed operation mode. The mode switch may select the DS-CDMA modem by switching and connecting to the DS-CDMA modem.

As can be appreciated from the above description of the UWB network system according to exemplary embodiments of the present invention, as the DS-CDMA type communication and the MB-OFDM type communication are shared in one device, system resources can be saved compared with using two different devices for each type of communication.

Further, when the system operates in one of the high-speed and the low-speed modes, the other mode is not used so that power can be saved.

Further, when the MB-OFDM type, which is incompatible with other sensor network systems, is used, an extra transceiver is not needed for the sensor network systems to subscribe.

Further, when the DS-CDMA type is used, low compatibility in the high-speed mode can be resolved.

Further, when the MB-OFDM transceiver and the DS-CDMA transceiver are used at the same time according to an exemplary embodiment of the present invention, the problem of the frequencies of each other's transceivers operating as noise and interference is resolved.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. An ultra wideband (UWB) network transmitter comprising:
a multi-band orthogonal frequency division multiplexing (MB-OFDM) modem which modulates a transmission signal using MB-OFDM;
a direct sequence code division multiple access (DS-CDMA) modem which modulates a transmission signal using DS-CDMA;
a mode switch which switches to the MB-OFDM modem or the DS-CDMA modem according to a mode control signal;
a phase lock loop (PLL) which shifts a phase of a frequency according to a phase control signal and locks the frequency used for MB-OFDM type modulation or the DS-CDMA type modulation; and
a central processing unit (CPU) which transmits the mode control signal to the mode switch and transmits the phase control signal to the PLL.

2. The UWB network transmitter of claim 1, wherein the mode control signal is a high-speed mode control signal or a low-speed mode control signal.

3. The UWB network transmitter of claim 1, wherein the CPU transmits the mode control signal to the mode switch and the phase control signal to the PLL, according to a mode selection input.

4. The UWB network transmitter of claim 1, further comprising:
a low-pass filter (LPF) which filters out a high frequency noise component of a signal output from the MS-OFDM modem or the DS-CDMA modem and passes a low frequency component of the signal;
a mixer which mixes the signal output from the LPF and an oscillation signal to up-convert the signal;
an amplifier which amplifies the up-converted signal;
a band-pass filter (BPF) which passes a frequency band of an MB-OFDM type or a frequency band of an DS-CDMA type;
a voltage control oscillator (VCO) which generates a voltage-controlled oscillation signal according to a control voltage; and
a multi-tone generator which receives the voltage-controlled oscillator signal and generates the oscillation signal as a local oscillation signal for an I channel and a Q channel.

5. The UWB network transmitter of claim 1, wherein when there is no data to be transmitted, the mode switch is switched to the DS-CDMA modem so that the UWB network transmitter is in a low-speed operation mode.

6. The UWB network transmitter of claim 1, wherein the CPU determines whether to keep a high-speed operation mode after transmitting data, and when it is determined that a low-speed operation mode is desired, the CPU transmits the low-speed mode control signal to the mode switch.

7. The UWB network transmitter of claim 1, wherein the PLL comprises:
a reference clock generator which generates a reference frequency;
a divider which divides the reference frequency to generate a division frequency;
a mixer which mixes the division frequency and a demultiply frequency to detect phase;
a LPF which blocks a high frequency noise component of a signal output from the mixer and passes a low frequency component of the signal; and
a low noise amplifier (LNA) which amplifies the signal output from the LPF and lowers a noise factor of the signal and transmits the signal to the VCO; and
a demultiplier which demultiplies the signal output from the VCO and generates a chip rate clock signal and a symbol rate clock signal.

8. An ultra wideband (UWB) network receiver comprising:
a multi-band orthogonal frequency division multiplexing (MB-OFDM) modem which demodulates digital reception data of an MB-OFDM type;
a direct sequence code division multiple access (DS-CDMA) modem which demodulates digital reception data of an DS-CDMA type;
an automatic gain controller (AGC) which controls the amplitude of an input signal and outputs the signal as an analog reception signal;
an analog-to-digital converter which converts the analog reception signal into the digital reception data;
a phase locked loop (PLL) which locks a phase of a frequency used for MB-OFDM or DS-CDMA;
a mode switch which switches the digital reception data to the MB-OFDM modem or the DS-CDMA modem according to a mode control signal; and
a central processing unit (CPU) which determines if data are processed according to the MB-OFDM type or the DS-CDMA type, transmits the mode control signal to the mode switch, and transmits a phase control signal to the PLL.

9. The UWB network receiver of claim 8, wherein the mode control signal is a high-speed mode control signal or a low-speed mode control signal.

10. The UWB network receiver of claim 8, further comprising:
an analog matched filter which integrates, samples, and holds an amplified signal; and
an amplifier which amplifies the input signal and outputs an amplified signal to the analog matched filter and the AGC;
wherein the PLL transmits a symbol rate clock to the analog matched filter to control the phase of the filtered signal.

11. The UWB network receiver of claim 8, further comprising:
a band pass filter (BPF) which filters a reception signal, and passes a signal of a frequency band of the MB-OFDM type or of the DS-CDMA type;
a low noise amplifier (LNA) which amplifies the signal from the BPF and lowers a noise factor of the UWB network receiver;
a VCO which generates an oscillation signal according to a control voltage from the PLL;
a mixer which mixes the amplified signal from the LNA and the oscillation signal;
a low pass filter (LPF) which blocks a high frequency noise component of the mixed signal and passes a signal of a low frequency band to the AGC; and
a multi-tone generator which generates the oscillation signal as a local oscillation signal of an I channel and a Q channel and transmits the oscillation signal to the mixer.

12. The UWB network receiver of claim 10, further comprising:
a band pass filter (BPF) which filters a reception signal, and passes a signal of a frequency band of the MB-OFDM type or of the DS-CDMA type;
a low noise amplifier (LNA) which amplifies the signal from the BPF and lowers a noise factor of the UWB network receiver;
a VCO which generates an oscillation signal according to a control voltage from the PLL;
a mixer which mixes the amplified signal from the LNA and the oscillation signal;
a low pass filter (LPF) which blocks a high frequency noise component of the mixed signal and passes a signal of a low frequency band to the AGC; and
a multi-tone generator which generates the oscillation signal as a local oscillation signal of an I channel and a Q channel and transmits the oscillation signal to the mixer.

13. The UWB network receiver of claim 8, wherein when there is no data received, the mode switch is switched to the DS-CDMA modem so that the UWB network transmitter is in the low-speed operation mode.

14. A method of switching transmission modes in an ultra wide band network transmitter, the method comprising:
receiving a command to transmit data; and
switching to a multi-band orthogonal frequency division multiplexing (MB-OFDM) modem to select a high-speed operation mode.

15. The method of claim 14, further comprising:
transmitting the data in the high-speed operation mode.

16. The method of claim 15, wherein after the data is transmitted, determining whether to remain in the high-speed operation mode, and when a low-speed operation mode is desired, switching to direct sequence code division multiple access (DS-CDMA) modem to select the low-speed operation mode.
